(19) United States
(12) Patent Application Publication
(10) Pub. No.: US 2026/0223677 A1
(43) Pub. Date: Jul. 30, 2026

(54) SEMICONDUCTOR DEVICE AND POWER CONVERSION DEVICE

(71) Applicant: ASTEMO, LTD., Chiyoda-ku, Tokyo (JP)

(72) Inventors: Yusuke TAKAGI, Hitachinaka-shi, Ibaraki (JP); Yujiro KANEKO, Hitachinaka-shi, Ibaraki (JP)

(73) Assignee: ASTEMO, LTD., Chiyoda-ku, Tokyo (JP)

(21) Appl. No.: 19/145,737

(22) PCT Filed: Jan. 27, 2023
(86) PCT No.: PCT/JP2023/002673

§ 371 Date: Jul. 3, 2025

(51) Int. Cl. H10W 40/47

(52) U.S. Cl. CPC H10W 40/47

(57) ABSTRACT

A semiconductor device and a power conversion device, the semiconductor device including a semiconductor module, include: a first cooling member and a second cooling member disposed respectively on both surfaces of the semiconductor module, the first cooling member and the second cooling member each having a refrigerant flowing inside thereof; a coupling member that couples a first opening that lets the refrigerant flow in and out of the first cooling member from and to the second cooling member, to a second opening that lets the refrigerant flow in and out of the second cooling member from and to the first cooling member; and a sealing member disposed on an outer periphery of the coupling member at a position between the first cooling member and the second cooling member. The coupling member has a coupling member end extending to the interior of the second cooling member, and the coupling member end includes a fixing part formed by bending the coupling member end along an inner wall surface of the second cooling member.

### TECHNICAL FIELD

The present invention relates to a semiconductor device and a power conversion device.

### BACKGROUND ART

In a structure of a power conversion device in which a water channel is provided in such a way as to sandwich a power module between a water channel running on the upper side and a water channel running on the lower side to cool the power module, a sealing portion disposed in a connection portion between the power module and the water channels on the upper and lower sides is exposed to a force acting in the direction of separating the power module from the water channels, the force being created by the pressure of a refrigerant flowing through the water channel. Because of this problem, a structure in which the reliability of the sealing portion is ensured by fixing the water channel with a leaf spring, a leaf spring holding member, a fastening member, and the like is generally adopted. For example, PTL listed below discloses a configuration of a cooling device in which a channel is formed by stacking components with fins formed thereon to allow manufacturing of the cooling device at low cost.

### CITATION LIST

### Patent Literature

PTL 1: JP 2022-029977 A

### SUMMARY OF INVENTION

### Technical Problem

According to the technique described in PTL 1, watertightness between the water channel on the upper side and the water channel on the lower side is provided by a sealing structure using an O-ring, and therefore fastening with bolts is necessary to hold the O-ring. In order to provide a device of a structure similar to the above structure with fewer bolted components, an object of the present invention is to provide a semiconductor device and a power conversion device that further reduce the number of components and improve productivity while maintaining cooling performance.

### Solution to Problem

A semiconductor device and a power conversion device, the semiconductor device including at least one semiconductor module having a semiconductor element, include: a first cooling member and a second cooling member disposed respectively on both surfaces of the semiconductor module, the first cooling member and the second cooling member each having a refrigerant flowing inside thereof; a coupling member that couples a first opening that lets the refrigerant flow in and out of the first cooling member from and to the second cooling member, to a second opening that lets the refrigerant flow in and out of the second cooling member from and to the first cooling member; and a sealing member disposed on an outer periphery of the coupling member at a position between the first cooling member and the second cooling member. The coupling member has a coupling member end extending to the interior of the second cooling member, and the coupling member end includes a fixing part formed by bending the coupling member end along an inner wall surface of the second cooling member.

### Advantageous Effects of Invention

A semiconductor device and a power conversion device that further reduce the number of components and improve productivity while maintaining cooling performance can be provided.

### BRIEF DESCRIPTION OF DRAWINGS

FIG. 1 is an electric circuit diagram of a power conversion device connected to a rotating electrical machine.

FIG. 2 is an electric circuit diagram of a semiconductor module of one phase.

FIG. 3 is an overall perspective view of a semiconductor device according to a first embodiment of the present invention.

FIG. 4 is an overall exploded view of the semiconductor device of FIG. 3.

FIG. 5 is a cross-sectional view of a connection portion between cooling members of the semiconductor device according to the first embodiment of the present invention (A-A cross-sectional view of FIG. 3).

FIG. 6 is an explanatory view of a method of forming a first fixing part according to the first embodiment of the present invention.

FIG. 7 is a cross-sectional view of a connection portion between cooling members of a semiconductor device according to a second embodiment of the present invention.

FIG. 8 is a cross-sectional view of a connection portion between cooling members of a semiconductor device according to a third embodiment of the present invention.

FIG. 9 is a cross-sectional view of a connection portion between cooling members of a semiconductor device according to a fourth embodiment of the present invention.

FIG. 10 is an overall perspective view of a semiconductor device according to a fifth embodiment of the present invention.

FIG. 11 is a cross-sectional view of a connection portion between cooling members of the semiconductor device of FIG. 10.

### DESCRIPTION OF EMBODIMENTS

Hereinafter, embodiments of the present invention will be described with reference to the drawings. The following description and drawings are examples for describing the present invention, and are omitted or simplified when necessary to make the description clear. The present invention can be implemented in various other forms. Unless otherwise specified, each constituent element may be provided as a singular element or as plural elements as well.

A position, size, shape, range, and the like of each constituent element shown in drawings may not represent the actual position, size, shape, range, and the like of the constituent element. This is done for the purpose of facilitating understanding of the invention. The present invention, therefore, is not necessarily limited by positions, sizes, shapes, ranges, and the like shown in the drawings.

### First Embodiment of the Present Invention and Overall Configuration

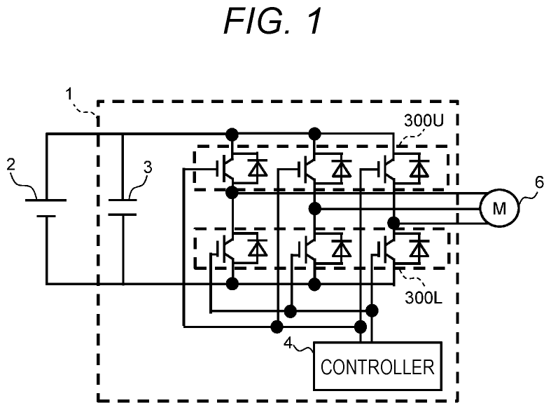

### (FIG. 1)

A power conversion device 1 is a device that converts DC power supplied by a DC power supply 2, which is a battery, into AC power and that outputs AC power to a motor 6. The power conversion device 1 includes a capacitor 3, a controller 4, upper arms 3000, and lower arms 300L. The capacitor 3 smooths DC power supplied from the DC power supply 2 to switching elements of the power conversion device 1. The controller 4 controls switching operations of the upper arms 300U and the lower arms 300L that are the switching elements, the switching operations being made for power conversion.

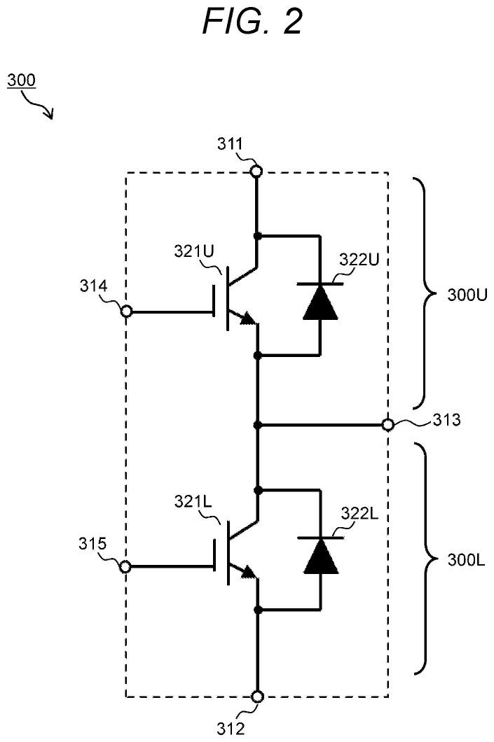

### (FIG. 2)

A semiconductor module 300 having a function of a power module includes power semiconductor elements 321U, 321 L, 322U, and 322 L. The power semiconductor elements 321U and 321L are insulated gate bipolar transistors (IGBTs). The power semiconductor elements 322U and 322L are diodes. The power semiconductor elements 321U, 321 L, 322U, and 322 L may be replaced with field effect transistors (FETs) or the like.

The semiconductor module 300 is composed of the upper arm 300U and the lower arm 300L that are described above. The upper arm 300U is composed of the power semiconductor element 321U and the diode 322U. The lower arm 300L is composed of the power semiconductor element 321L and the diode 322L. The upper arm 300U has a DC positive electrode terminal 311 and a signal terminal 314. The lower arm 300L has a DC negative electrode terminal 312 and a signal terminal 315.

The DC positive terminal 311 and the DC negative terminal 312 are connected to the capacitor 3 and the like, and supply power coming from outside of the semiconductor module 300 to the power semiconductor elements 321U, 321 L, 3220, and 322 L. The signal terminals 314 and 315 are connected to a control board carrying the above controller 4. As a result, the power semiconductor elements 3210 and 321L have their switching operations controlled by the controller 4.

The semiconductor module 300 includes an AC terminal 313. The AC terminal 313 electrically connects the upper arm 300U and the lower arm 300L, and outputs AC power, which is generated through DC/AC conversion by the power semiconductor elements 321U and 321L serving as switching elements, to the outside of the semiconductor module 300.

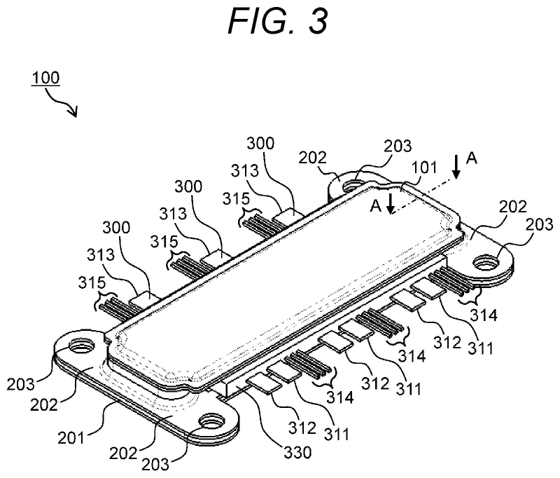

### (FIG. 3)

A semiconductor device 100 constituting the above power conversion device 1 has a configuration of a semiconductor unit with a cooler, and includes at least one semiconductor module 300 having semiconductor elements, a first cooling member 101, and a second cooling member 201. As shown in FIG. 3, the semiconductor device 100 includes semiconductor modules 300 of three phases, which make up a three-phase power conversion circuit. The semiconductor modules 300 of three phases are mold-sealed with a sealing resin 330.

The positive electrode terminal 311 of each semiconductor module 300 is exposed from the sealing resin 330. The negative electrode terminal 312 of each semiconductor module 300 is exposed from the sealing resin 330. The AC terminal 313 of each semiconductor module 300 is exposed from the sealing resin 330. The signal terminals 314 and 315 of each semiconductor module 300 are exposed from the sealing resin 330.

The first cooling member 101 and the second cooling member 201 are disposed respectively on both surfaces of the semiconductor module 300, which is therefore in contact with the first cooling member 101 and with the second cooling member 201. Being sandwiched between the first cooling member 101 and the second cooling member 201 in this manner, the semiconductor module 300 is cooled by a refrigerant flowing inside the first cooling member 101 and the second cooling member 201.

The second cooling member 201 has at least four flanges 202. Each flange 202 has a through-hole 203. A fastening member, such as a screw or a bolt, is inserted into the through-hole 203. As a result, the semiconductor device 100 is fixed to a housing (not illustrated) of the power conversion device 1.

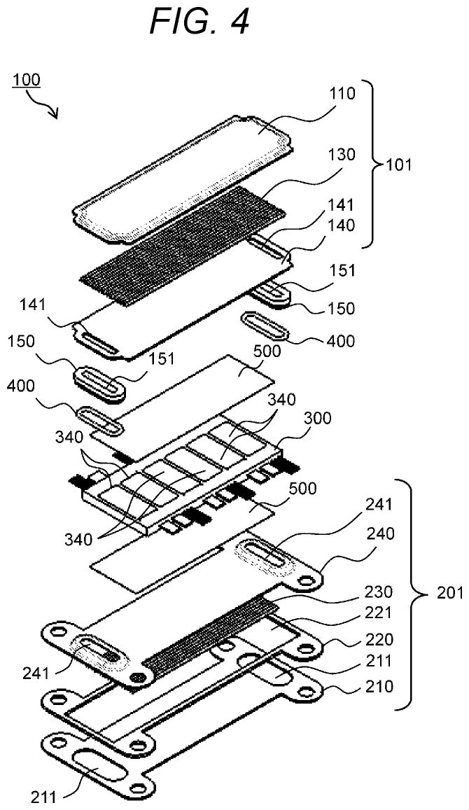

### (FIG. 4)

The semiconductor module 300 has a plurality of heat release surfaces 340 for releasing internal heat of the semiconductor module 300. The heat release surfaces 340 are formed on both surfaces of the semiconductor module 300 (a back surface of the semiconductor module 300 is not shown in FIG. 4), and are exposed surfaces not mold-sealed with the above sealing resin 330. Having such heat release surfaces 340, the semiconductor module 300 releases its generated heat to the outside of the semiconductor module 300.

A bonding member 500 is disposed between the semiconductor module 300 and the first cooling member 101 and another bonding member 500 is disposed between the semiconductor module 300 and the second cooling member 201. These bonding members 500 are thermally conductive and insulative, and are provided such that the semiconductor module 300 is sandwiched between the bonding members 500. Each bonding member 500 is thermally connected to the heat release surfaces 340. This configuration improves the reliability of connection between the semiconductor module 300 and the cooling members 101 and 201. It should be noted that the bonding member 500 does not always have to be insulative when an insulating layer is provided inside the semiconductor module 300.

The first cooling member 101 includes a cover 110, a first fin 130, and a first fin base 140. The first cooling member 101 is connected to coupling members 150. These members are aluminum-based alloys or copper-based alloys, and are joined together by such a joining method as brazing.

The first fin base 140 has two first fin base openings 141. The first fin base openings 141 are openings that let the refrigerant flow in and out of the first cooling member 101, from and to the second cooling member 201. The first fin base openings 141 are formed on both ends of the first fin base 140 across the first fin 130 placed between the first fin base openings 141 on the first fin base 140.

The first cooling member 101 includes a first fin housing portion 111 housing the first fin 130 serving as a heat release fin that releases heat from the semiconductor module 300. This first fin housing portion 111 will be described later. The first fin housing portion 111 is housed in the first fin housing portion 111 formed by the cover 110 and the first fin base 140, and is joined to the cover 110 and to the first fin base 140.

Each coupling member 150 has a coupling channel 151. The coupling member 150 is joined to the first fin base 140. The coupling member 150 is disposed at a position at which the coupling channel 151 and the first fin base opening 141 communicate with each other to form a channel.

The second cooling member 201 includes a water channel base 210, a frame 220, a second fin 230, and a second fin base 240. These members are aluminum-based alloys or copper-based alloys, and are joined together by such a joining method as brazing.

The water channel base 210 has two water channel base openings 211. The water channel base openings 211 let the refrigerant flow in and out of the second cooling member 201. The water channel base openings 211 are formed on both ends of the water channel base 210 across the second fin 230 placed between the water channel base openings 211 on the water channel base 210. One of the two water channel base openings 211 serves as a lead-in opening for leading the incoming refrigerant into the second cooling member 201, and the other of the same serves as a discharge opening for discharging the refrigerant out of the second cooling member 201. The water channel base openings 211 are openings that are formed at a position counter to a fixing part 154, which will be described later, in the second cooling member 201.

The frame 220 includes a second fin housing portion 221 housing the second fin 230 serving as a heat release fin that releases heat from the semiconductor module 300. The second fin base 240 has two second fin base openings 241. The second fin base openings 241 are formed on both ends of the second fin base 240 across the second fin 230 placed between the second fin base openings 241 on the second fin base 240.

The two second fin base openings 241 are openings that let the refrigerant flow in and out of the second cooling member 201, from and to the first cooling member 101. The refrigerant coming in through the water channel base opening 211 flows from the second cooling member 201 to the first cooling member 101 through one of the two second fin base openings 241 and flows from the first cooling member 101 back to the second cooling member 201 through the other of the two second fin base openings 241.

The second fin 230 is housed in the second fin housing portion 221, and has both surfaces sandwiched between the water channel base 210 and the second fin base 240 and joined to the water channel base 210 and the second fin base 240. The frame 220 has its both surfaces sandwiched between the water channel base 210 and the second fin base 240 and joined to the water channel base 210 and the second fin base 240, thus forming the second fin housing portion 221.

The first cooling member 101 and the second cooling member 201 are arranged such that the coupling channels 151 of the coupling members 150, the first fin base openings 141, and the second fin base openings 241 communicate each other to form a single channel. In this configuration, therefore, the coupling members 150 couple the first fin base openings 141 to the second fin base openings 241.

A sealing member 400 is disposed on the outer periphery of the coupling member 150 at a position between the first cooling member 101 and the second cooling member 201 in such a way as to be in contact with the coupling member 150 and with the second fin base 240. This ensures the watertightness of a connection portion between the coupling member 150 and the second cooling member 201.

The flow of the refrigerant will be described. When the refrigerant is supplied to the second cooling member 201 from one of its two water channel base openings 211, a path through which the refrigerant flows branches at the second cooling member 201, into a path through which the refrigerant flows toward the second fin 230 of the second fin housing portion 221 and into a path through which the refrigerant flows from the second fin base opening 241 toward the first fin housing portion 111 through one coupling channel 151. The refrigerant having passed through the first fin 130 in the first fin housing portion 111 flows back to the second cooling member 201 through the other coupling channel 151, and joins the refrigerant having passed through the second fin 230, and then the joined refrigerant flows out of the second cooling member 201 through the other one of the water channel base openings 211.

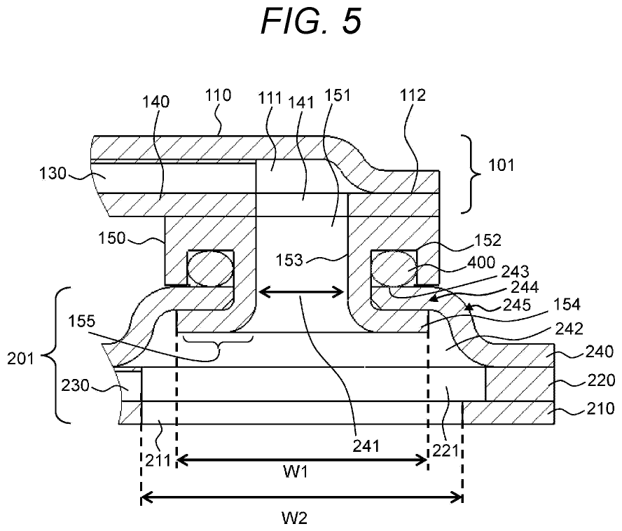

### (FIG. 5)

FIG. 5 is an A-A cross-sectional view of FIG. 3. In the first cooling member 101, the cover 110 and the first fin base 140 form the first fin housing portion 111. The first fin 130 is placed in the first fin housing portion 111.

The coupling member 150 couples the first cooling member 101 to the second cooling member 201. The coupling member 150 has a sealing member housing portion 152 on its outer periphery, the sealing member housing portion 152 being located between the first cooling member 101 and the second cooling member 201. The sealing member housing portion 152 houses the sealing member 400 such that the sealing member 400 is in close contact with an outer wall surface of the second fin base 240. This ensures the watertightness of a water channel between the first cooling member 101 and the second cooling member 201.

The second fin base 240 has a sealing member setting portion 243. The sealing member setting portion 243 is a peripheral part of the second fin base opening 241 and is a part of the outer wall surface of the second fin base 240, the outer wall surface being in close contact with the sealing member 400. Thus, by bringing the sealing member 400 into close contact with the sealing member setting portion 243, the watertightness of the water channel between the first cooling member 101 and the second cooling member 201 is ensured.

In the second cooling member 201, the second fin base 240 has a sloped part 245 sloped toward the first cooling member 101, and a flat part 244 extending from the sloped part 245 to an outer peripheral surface of the coupling member 150 to come in contact with the outer peripheral surface. The sealing member setting portion 243 is formed on the flat part 244.

The coupling member 150 has a coupling member end 155 extending to the interior of the second cooling member 201. The coupling member end 155 includes a fixing part 154 formed by bending the coupling member end 155 toward an inner wall surface of the second cooling member 201.

The coupling member 150 has a coupling channel wall 153 with which the refrigerant flowing in the coupling channel 151 and the second cooling member 201 comes into contact. The coupling channel wall 153 is inserted into the second cooling member 201 through the second fin base opening 241. The coupling channel wall 153 is bent toward a channel inner wall surface of the second fin base 240 so that the sealing member setting portion 243 keeps the sealing member 400 housed in the sealing member housing portion 152. In this configuration, the sealing member 400 and the sealing member setting portion 243 are in contact with each other, and the fixing part 154 that keeps the sealing member 400 in the sealing member housing portion 152 is formed inside the second cooling member 201.

The second fin base 240 forms a coupling channel housing portion 242 by the flat part 244 and the sloped part 245 that the second fin base 240 has. The coupling channel housing portion 242 has a space in which the fixing part 154 formed in the second cooling member 201 can be housed. Because the coupling member end 155 is bent to form the fixing part 154, it is preferable that the height of the coupling channel housing portion 242 be larger than the thickness of the fixing part 154. In this configuration, in the second cooling member 201, the flow of the refrigerant toward the second fin 230 is not hindered by the thickness of the fixing part 154, and therefore a drop in the cooling performance of the second cooling member 201 caused by the hindered flow of the refrigerant can be prevented.

As show in FIG. 5, the diameter W2 of the water channel base opening 211 is larger than an inner diameter W1 across left and right front ends of the fixing part 154. As a result, a tool for forming the fixing part 154 through the water channel base opening 211, which tool will be descried later, is easily inserted into the second cooling member 201, and the fixing part 154 can be formed after the first cooling member 101 and the second cooling member 201 are assembled. This improves productivity.

In the first cooling member 101, the cover 110 has a cover brazing portion 112. On the cross-section of FIG. 5, the cover brazing portion 112 is formed at a position at which the sealing member 400 and the fixing part 154 overlap in the thickness direction of the semiconductor device 100 (the vertical direction in FIG. 5).

The cover brazing portion 112 bears a pressing force applied from the first fin base 140 to the first cover 110, the pressing force being part of a pressing force against the fixing part 154 that is generated when the fixing part 154 is formed by a fixing part forming tool for forming the fixing part 154, which fixing part forming tool will be described later. This suppresses deformation of the first cooling member 101, which is likely to occur when the fixing part 154 is formed.

On the cross-section of FIG. 5, the first fin 130 is longer in its longitudinal direction (the horizontal direction in FIG. 5) than the second fin 230. In the cross-sectional view of FIG. 5, a part of the first fin 130 is located at a position where the first fin 130 overlaps the sealing member 400 and the fixing part 154 in a stacking direction of the semiconductor device 100 (the vertical direction in FIG. 5) in the first cooling member 101.

The first fin 130 bears a pressing force applied from the first fin base 140 to the interior of the first cooling member 101, the pressing force being part of a pressing force against the fixing part 154 that is generated when the fixing part 154 is formed by the tool for forming the fixing part 154, which tool will be described later. This suppresses deformation of the first cooling member 101, which is likely to occur when the fixing part 154 is formed.

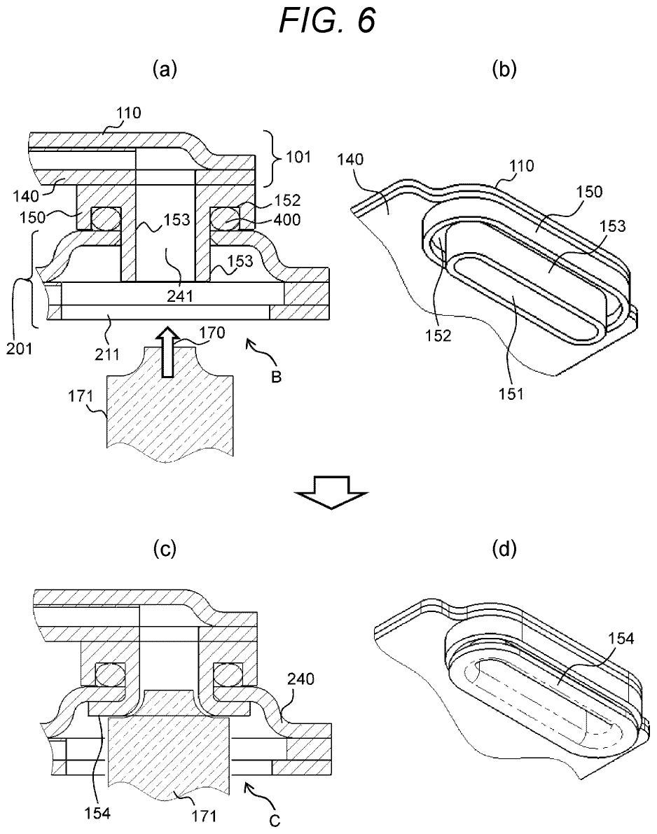

### (FIG. 6)

FIG. 6(a) is a cross-sectional view of a connecting portion between the cooling members of the semiconductor device before formation of the fixing part 154, FIG. 6(b) is a perspective view of the semiconductor device of FIG. 6(a) seen from a viewpoint B, showing a perspective view of the semiconductor device from which the second cooling member 201 and the sealing member 400 are removed, FIG. 6(c) is a cross-sectional view of a connecting portion between the cooling members of the semiconductor device after formation of the fixing part 154, and FIG. 6(d) is a perspective view of the semiconductor device of FIG. 6(c)) seen from a viewpoint C, showing a perspective view of the semiconductor device from which the second cooling member 201, the sealing member 400, and a fixing part forming tool 171 are removed.

As shown in FIG. 6(a), the sealing member 400 is housed in the sealing member housing portion 152 of the first cooling member 101. The coupling member 150 has its part inserted in the second fin base opening 241. Right and left parts of the coupling channel wall 153 of the coupling member 150 are pressed and bent in a direction in which a space between both parts are widened, by the fixing part forming tool 171 inserted in an insertion direction 170 through the water channel base opening 211. As a result, as shown in FIG. 6(c), the coupling channel wall 153 is pressed against the second fin base 240 to join thereto, which forms the fixing part 154.

The fixing part 154 is formed as a part extending from the second fin base opening 241 and remaining in close contact with an inner wall surface of the second fin base 240. This increases a force holding the sealing member 400, thus offering the high watertightness of the channel. It should be noted that in any case where the force holding the sealing member 400 can be maintained, forming the fixing part 154 along the whole second fin base opening 241 is unnecessary. In such a case, the fixing part 154 may be formed on a part of the second fin base opening 241 only.

In this configuration, a leaf spring or a reinforcing plate, which is needed when the coupling member 150 coupled to the first cooling member 101 is fixed to the second cooling member 201 in a conventional structure, is no longer needed. This allows a reduction in the number of components, thus improving productivity.

### Second Embodiment

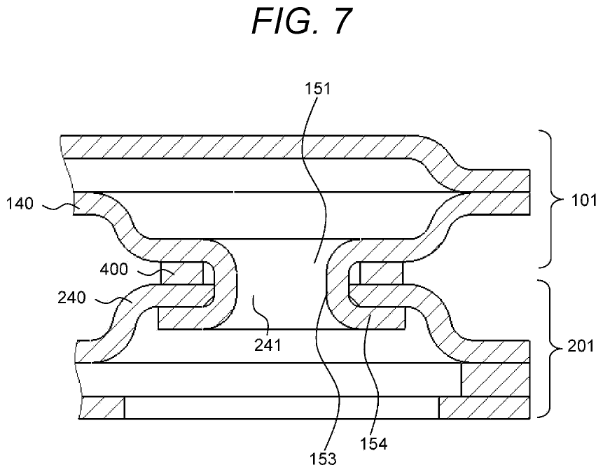

### (FIG. 7)

In a second embodiment, the coupling member 150 provided in the first embodiment for connecting the first cooling member 101 and the second cooling member 201 is not provided. Instead, a part of the first fin base 140 of the first cooling member 101 extends to the second cooling member 201 via the second fin base opening 241. As a result, the coupling channel 151 is formed by an integral structure in which the first fin base 140 and the coupling member 150 are combined together.

The first fin base 140 is identical in shape with the second fin base 240, and this provides a space with a height equal to the height of the above semiconductor module 300 disposed between the first cooling member 101 and the second cooling member 201.

The above fixing part forming tool 171 presses the coupling channel wall 153 of the second fin base 240, from the second cooling member 201 side, thus forming the fixing part 154. The sealing member 400 has a rectangular cross-sectional shape, and is in contact with respective outer walls of the first fin base 140 and the second fin base 240. As the fixing part 154 is formed, therefore, the sealing member 400 is pressed and fixed between these outer walls. In this configuration, the number of components can be reduced and productivity is improved as well.

### Third Embodiment

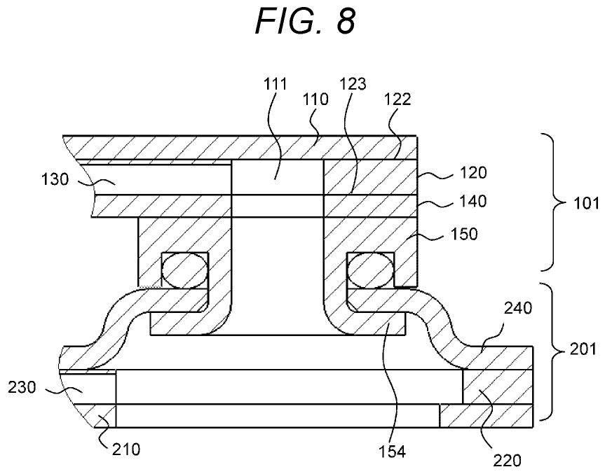

### (FIG. 8)

The first cooling member 101 includes the cover 110, a first frame 120, and the first fin base 140. A third embodiment is different from the first embodiment in that the cover 110 has a different shape and that the first frame 120 is added to the first cooling member 101.

The first frame 120 has the first fin housing portion 111. The first fin 130 is placed in the first fin housing portion 111. The first frame 120 is a part of a channel wall of the first cooling member 101, and has a cover joining part 122 and a first fin base joining part 123 that are formed respectively on both surfaces of the first frame 120. The second cooling member 201 has the same structure as that of the second cooling member 201 in the above-described embodiments. A second frame 220 forms a part of a channel wall of a channel formed inside the second cooling member 201.

The cover joining part 122 joins the cover 110 to the first frame 120. The first fin base joining part 123 joins the first frame 120 to the first fin base 140. The cover 110 is a member of a plate shape.

The first cooling member 101 thus includes the first fin base 140, which is a base member joined to the heat release fin 130, the first frame 120, which is a frame member forming a space for placing the heat release fin 130 therein, and the first cover 110, which is a plate member that is counter to the first fin base 140 across the first frame 120 interposed therebetween and that is joined to the first frame 120 to form a channel inside the first cooling member 101.

The second cooling member 201 includes the second fin base 240, which is a base member joined to the heat release fin 230, the second frame 220, which is a frame member forming a space for placing the heat release fin 230 therein, and the water channel base 210, which is a plate member that is counter to the second fin base 240 across the second frame 220 interposed therebetween and that is joined to the second frame 220 to form a channel inside the second cooling member 201.

Because of such a structure, when the fixing part 154 is formed, a load bearing jig (not illustrated) that bears a pressure applied by the above fixing part forming tool 171 can be disposed on the outer surface of the cover 110, in which case the shape of the disposed jig can be simplified. In addition, easiness in bending the channel wall to form fixing parts 154 and 164 is improved, which improves productivity. Further, a degree of freedom in determining an area and placement of a cover sealing member (of which details will be described later), which is brought into close contact with plate members 110 and 210 when their opening are not used, is improved. This contributes to miniaturization.

### Fourth Embodiment

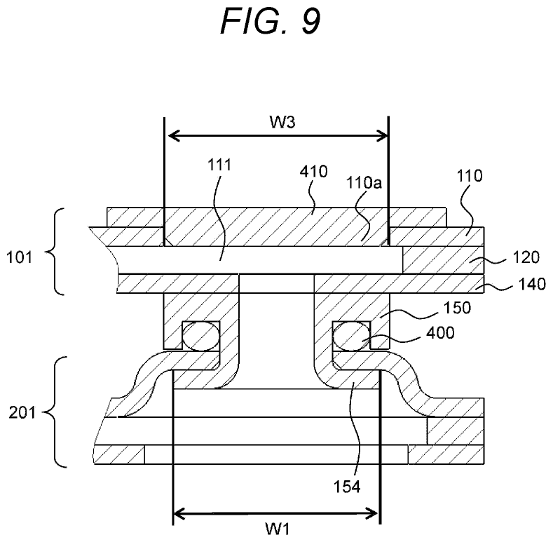

### (FIG. 9)

In a fourth embodiment, a first cover opening 110a is formed on the cover 110 of the third embodiment. The cooling member 101, which is a plate member, includes the cover opening 110a that lets the refrigerant flow in and out, and a cover sealing member 410 that hermetically seals the cover opening 110 a, the cover opening 110a and cover sealing member 410 being located counter to the coupling member 150.

On a cross-section shown in FIG. 9, the cover opening 110a is formed at a position at which the cover opening 110a overlaps the fixing part 154 and the sealing member 400 in the stacking direction. The cover sealing member 410 closes up the cover opening 110a to provide watertightness against the refrigerant flowing inside the cover 110. By removing the cover sealing member 410 from the first cooling member 101, a structure in which another layer is added to a layered structure of the water channel can be handled. The cover sealing member 410 is fixed or bonded to the first cooling member 101 by using a fixing member (not illustrated) that, from the outside, fixes the cover sealing member 410 to the first cooling member 101 or applying an adhesive to the surface of the cooling member 101 to bond the cover sealing member 410 to the first cooling member 101.

The diameter W3 of the cover opening 110a is larger than the inner diameter W1 across left and right front ends of the fixing part 154. As a result, when the fixing part 154 is formed by the above fixing part forming tool 171, a load bearing jig (not illustrated) of the size corresponding to the size of the fixing part forming tool 171 is easily inserted into the first cooling member 101 through the cover opening 110a. In this configuration, deformation of the first cooling member 101 by a load applied thereto can be suppressed, which improves productivity.

### Fifth Embodiment

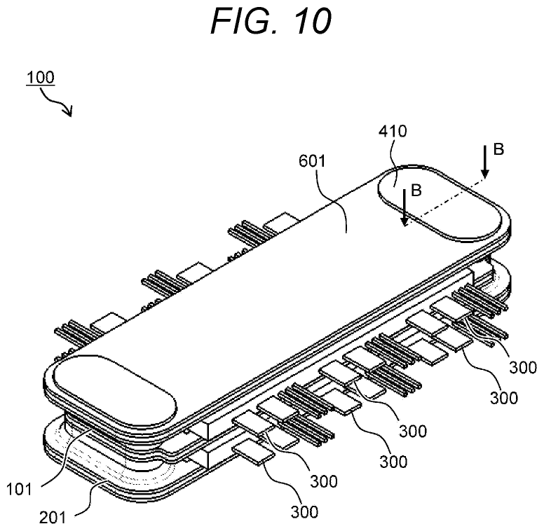

### (FIG. 10)

The semiconductor device 100 may be of a two-tier structure in which two tiers of semiconductor modules 300 of three phases are stacked up. The semiconductor device 100 of the two-tier structure includes the first cooling member 101, the second cooling member 201, and a third cooling member 601. The third cooling member 601 includes two cover sealing members 410 for sealing up the refrigerant inside. The third cooling member 601 includes the two cover sealing members 410, and these cover sealing members 410 may be removed to create openings. By doing this, a case where another layer needs to be added to a layered structure of the water channel can be handled.

The first cooling member 101 and the second cooling member 201 are arranged with semiconductor modules 300 of three phases sandwiched therebetween. In the same manner, the first cooling member 101 and the third cooling member 601 are arranged with semiconductor modules 300 of three phases sandwiched therebetween.

This configuration allows more semiconductor modules 300 than in the above embodiments to be incorporated in the semiconductor device 100, offers two systems for three-phase power output, and allows construction of the semiconductor device 100 in which arrays of semiconductor modules 300 are connected in parallel with each other to generate a large amount of power. It should be noted that the number of semiconductor modules 300 is not limited to six as shown in FIG. 10 and that additional semiconductor modules 300 may be further incorporated.

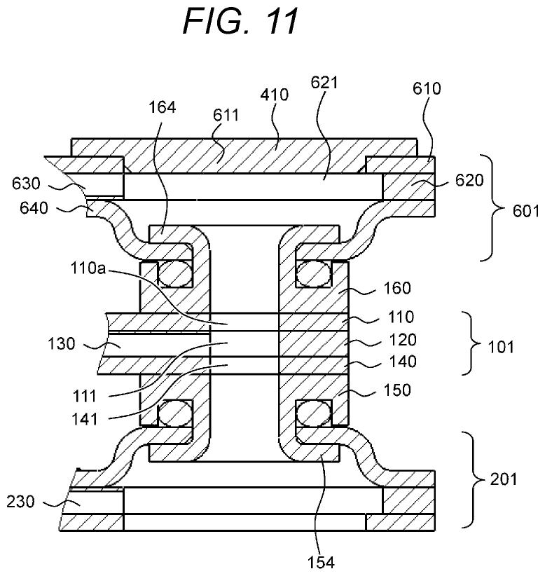

### (FIG. 11)

The first cooling member 101 includes a first cover 110, the first frame 120, the first fin 130, and a second cover 140. The first cooling member 101 is connected to a first coupling member 150 and to a second coupling member 160.

The first cover 110 has the first cover opening 110a. The second cover 140 has a second cover opening 141. The first cooling member 101 includes the first fin housing portion 111. The first fin 130 is housed in the first fin housing portion 111.

In the first cooling member 101, the first cover opening 110a, the second cover opening 141, and the first fin housing portion 111 communicate with each other. This forms a channel through which the refrigerant flows from the second cooling member 201 to the third cooling member 601 via the first cooling member 101.

As shown in FIG. 11, the first cover 110 and the second cover 140 may be identical in shape. When the first cover 110 and the second cover 140 are identical in shape, they can be manufactured by press molding using the same mold, in which case productivity is improved.

The second coupling member 160 is identical in configuration with the first coupling member 150, and connects the first cooling member 101 to the third cooling member 601 through a water channel. A third fin base 640 is identical in configuration with the second fin base 240. A fixing part 164 formed in the third cooling member 601 is identical in shape with the fixing part 154 formed in the second cooling member 201, and is formed by the same method by which the fixing part 154 is formed.

A third fin 630, which is a heat release fin that releases heat from the semiconductor module 300, is housed in a third fin housing portion 621 formed by a third frame 620 included in the third cooling member 601. The cover sealing member 410 is in close contact with a third cover opening 611 formed on a third cover 610 of the third cooling member 601, thus providing the third cooling member 601 with watertightness.

When the first coupling member 150 and the second coupling member 160 are identical in shape, the same mold can be used to manufacture the first and second coupling members 150 and 160, and therefore productivity is improved. As shown in a cross-sectional view of FIG. 11, the first coupling member 150 and the second coupling member 160 are arranged at a position at which they overlap in the stacking direction. This arrangement allows simultaneous formation of the first fixing part 154 in the second cooling member 201 and the second fixing part 164 in the third cooling member 601, thus improving productivity.

The above-described embodiments of the present invention offer the following advantageous effects.
(1) The semiconductor device including at least one semiconductor module 300 having a semiconductor element include: the first cooling member 101 and the second cooling member 201 disposed respectively on both surfaces of the semiconductor module 300, the first cooling member 101 and the second cooling member 201 each having the refrigerant flowing inside thereof; the coupling member 150 that couples the first opening 141 that lets the refrigerant flow in and out of the first cooling member 101 from and to the second cooling member 201, to the second opening 241 that lets the refrigerant flow in and out of the second cooling member 201 from and to the first cooling member 101; and the sealing member 400 disposed on the outer periphery of the coupling member 150 at a position between the first cooling member 101 and the second cooling member 201. The coupling member 150 has a coupling member end 155 extending to the interior of the second cooling member 201. The coupling member end 155 includes the fixing part 154 formed by bending the coupling member end 155 toward the inner wall surface of the second cooling member 201. Because of this configuration, the semiconductor device 100 that further reduces the number of components and improves productivity while maintaining cooling performance can be provided.
(2) In the second cooling member 201, the diameter W2 of a third opening 211 formed at the position at which the third opening 211 is counter to the fixing part 154 is larger than the inner diameter W1 across the left and right front ends of the fixing part 154. Because of this configuration, the fixing part forming tool 171 for forming the fixing part 154 can be easily inserted into the second cooling member 201 through the third opening 211.
(3) The second cooling member 201 includes the sloped part 245 sloped toward the first cooling member 101, and the flat part 244 extending from the sloped part 145 to the outer peripheral surface of the coupling member 150 to come in contact with the outer peripheral surface. Because of this configuration, the space in which the fixing part 154 can be housed is provided in the channel, and the flow of the refrigerant toward the fin is not hindered by the thickness of the fixing part 154. A drop in the cooling performance, therefore, can be prevented.
(4) The first cooling member 101 and the second cooling member 201 include a base member 140 and a base member 240 joined to the heat release fin 130 and the heat release fin 230, respectively, a frame member 120 and a frame member 220 forming spaces for placing the heat release fin 130 and the heat release fin 230 therein, respectively, and a plate member 110 and a plate member 210 that are disposed counter to the base member 140 and the base member 240 across the frame member 120 and the frame member 220 interposed therebetween and that are joined to the frame member 120 and the frame member 220 to form channels inside the first cooling member 101 and the second cooling member 201, respectively. Because of this configuration, a degree of freedom in determining an area and placement of the cover sealing member on the plate members 110 and 210 is improved, which contributes to miniaturization. In addition, easiness in bending the channel wall to form fixing parts 154 and 164 is improved, which improves productivity.
(5) The plate member 110 has a fourth opening 110a located counter to the coupling member 150, the fourth opening 110a letting the refrigerant flow in and out. Because of this configuration, the load bearing jig that deals with a pressure applied by the fixing part forming tool 171 can be inserted in the cooling member 101. As a result, productivity is improved. A degree of freedom in designing the first cover opening 110a is improved as well.
(6) The diameter W3 of the cover opening 110a is larger than the inner diameter W1 across the left and right front ends of the fixing part 154. As a result, when the fixing part 154 is formed, the load bearing jig of the size corresponding to the size of the fixing part forming tool 171 is easily inserted into the first cooling member 101 through the cover opening 110a. This improves productivity.
(7) A bonding member 500 is disposed between the semiconductor module 300 and the first cooling member 101 and another bonding member 500 is disposed between the semiconductor module 300 and the second cooling member 201. This configuration improves connection reliability between the semiconductor modules 300 and the cooling members 101 and 201.
(8) The power conversion device 1 including the semiconductor device 100 having the above configuration is adopted. Hence the power conversion device 1 that further reduces the number of components and improves productivity while maintaining cooling performance can be provided.

It should be noted that the present invention is not limited to the above embodiments and that various modifications and other configurations can be combined within a range where such modifications and configurations do not depart from the substance of the present invention. The present invention is not limited to an embodiment including all constituent elements described above, and includes an embodiment from which some constituent elements are deleted.

### REFERENCE SIGNS LIST

1 power conversion device
2 DC power supply
3 capacitor
4 controller
6 motor
100 semiconductor device
101 first cooling member
110 cover
110a first cover opening
111 first fin housing portion
112 cover brazing portion
120 first frame (frame member)
122 cover joining part
123 first fin base joining part
130 first fin
140 first fin base (second cover)
141 first fin base opening (second cover opening)
150 coupling member (first coupling member)
151 coupling channel
152 sealing member housing portion
153 coupling channel wall
154 fixing part (first fixing part)
155 coupling member end
160 second coupling member
164 second fixing part
170 insertion direction
171 fixing part forming tool
201 second cooling member
202 flange
203 through-hole
210 water channel base
211 water channel base opening
220 frame (second frame)
221 second fin housing portion
230 second fin
240 second fin base
241 second fin base opening
242 coupling channel housing portion
243 sealing member setting portion
244 flat part
245 sloped part
300 power module
311 positive electrode terminal
312 negative electrode terminal
313 AC terminal
314, 315 signal terminal
330 sealing resin
400 sealing member
410 cover sealing member
500 bonding member
601 third cooling member
610 third cover
611 third cover opening
620 third frame
621 third fin housing portion
630 third fin
640 third fin base

1. A semiconductor device including at least one semiconductor module having a semiconductor element, the semiconductor device comprising:
a first cooling member and a second cooling member disposed respectively on both surfaces of the semiconductor module, the first cooling member and the second cooling member each having a refrigerant flowing inside thereof;
a coupling member that couples a first opening that lets the refrigerant flow in and out of the first cooling member from and to the second cooling member, to a second opening that lets the refrigerant flow in and out of the second cooling member from and to the first cooling member; and
a sealing member disposed on an outer periphery of the coupling member at a position between the first cooling member and the second cooling member,
wherein the coupling member has a coupling member end extending to interior of the second cooling member, and
the coupling member end includes a fixing part formed by bending the coupling member end along an inner wall surface of the second cooling member.

2. The semiconductor device according to claim 1, wherein in the second cooling member, a diameter of a third opening is larger than an inner diameter across left and right front ends of the fixing part, the third opening being formed at a position at which the third opening is counter to the fixing part and letting the refrigerant flow in and out.

3. The semiconductor device according to claim 1, wherein
the second cooling member includes:
a sloped part sloped toward the first cooling member; and
a flat part extending from the sloped part to an outer peripheral surface of the coupling member to come in contact with the outer peripheral surface.

4. The semiconductor device according to claim 1, wherein
the first cooling member and the second cooling member each include:
a base member joined to a heat release fin;
a frame member forming a space for placing the heat release fin therein; and
a plate member that is disposed counter to the base member across the frame member interposed therebetween and that is joined to the frame member to form a channel inside one of the first cooling member or the second cooling member.

5. The semiconductor device according to claim 4, wherein the plate member has a fourth opening located counter to the coupling member, the fourth opening letting the refrigerant flow in and out.

6. The semiconductor device according to claim 5, wherein a diameter of the fourth opening is larger than an inner diameter across left and right front ends of the fixing part.

7. The semiconductor device according to claim 1, wherein a bonding member is disposed between the semiconductor module and the first cooling member, and another bonding member is disposed between the semiconductor module and the second cooling member.

8. A power conversion device comprising the semiconductor device according to any one of claim 1.
